(19) United States
(12) Patent Application Publication
(10) Pub. No.: US 2026/0312347 A1
(43) Pub. Date: Oct. 8, 2026

(54) ELECTRICAL CONNECTION UNIT

(71) Applicant: Yazaki Corporation, Tokyo (JP)

(72) Inventor: Ryu SENOO, Kakegawa-shi (JP)

(73) Assignee: Yazaki Corporation, Tokyo (JP)

(21) Appl. No.: 19/553,609

(22) Filed: Mar. 2, 2026

(30) Foreign Application Priority Data
Apr. 7, 2025 (JP) 2025-062953

(51) Int. Cl. H01R 25/16; H01R 13/50; H01R 13/533; H05K 7/20

(52) U.S. Cl. CPC H01R 25/161; H01R 13/50; H01R 13/533; H05K 7/20472; H05K 7/2049

(57) ABSTRACT

An electrical connection unit according to an embodiment includes an electronic component that has a first terminal, a first metal block, and an insulation portion. The first metal block is adjacent to the first terminal in a first direction and electrically connected to the first terminal. The first metal block has an end surface in the first direction and a peripheral surface extending from a peripheral edge of the end surface in the first direction. The insulation portion covers at least a part of the peripheral surface.

### BACKGROUND OF THE INVENTION

### Field of the Invention

Embodiments of the present invention relate to an electrical connection unit.

Priority is claimed on Japanese Patent Application No. 2025-062953 filed in Japan on April 7, 2025, the content of which is incorporated herein by reference.

### Description of Related Art

In the electrical connection unit, it is known that electronic components such as relays and resistors are mounted on a mounting surface of a housing.

In the electrical connection unit described in Patent Document 1, it is known that relays are mounted on a mounting surface of a housing. In order to improve the heat dissipation of the electronic components of the relays, plate members bent in an L-shape are connected respectively to two terminals of each of the relays by being arranged side by side, and the plate members are used as heat dissipation members.

### Prior art document

### Patent document

Patent Document 1: Japanese Unexamined Patent Application, First Publication No. 2022-123489

### SUMMARY OF THE INVENTION

In the electrical connection unit described in Patent Document 1, in a case where the heat dissipation members connected to the terminals are arranged side by side, it may be required to secure an insulation distance.

An embodiment provides an electrical connection unit capable of securing an insulation distance.

An electrical connection unit according to an embodiment includes an electronic component that has a first terminal, a first metal block, and an insulation portion. The first metal block is adjacent to the first terminal in a first direction and electrically connected to the first terminal. The first metal block has an end surface in the first direction and a peripheral surface extending from a peripheral edge of the end surface in the first direction. The insulation portion covers at least a part of the peripheral surface.

According to the embodiment, the insulation distance can be secured.

### BRIEF DESCRIPTION OF THE DRAWINGS

FIG. 1 is a perspective view illustrating an electrical connection unit according to an embodiment.

FIG. 2 is an exploded perspective view illustrating an electrical connection unit according to the embodiment.

FIG. 3 is a partially exploded perspective view illustrating an electrical connection unit according to the embodiment.

FIG. 4 is another partially exploded perspective view illustrating an electrical connection unit according to the embodiment.

FIG. 5 is a plan view illustrating an electrical connection unit according to the embodiment.

FIG. 6 is a cross-sectional view taken along line F6-F6 of a structure illustrated in FIG. 5.

FIG. 7 is a cross-sectional view taken along line F7-F7 of a structure illustrated in FIG. 5.

FIG. 8 is a cross-sectional view taken along line F8-F8 of a structure illustrated in FIG. 5.

FIG. 9 is a perspective view illustrating a part of an electrical connection unit according to the embodiment;

FIG. 10 is a cross-sectional view taken along line F10-F10 of a structure illustrated in FIG. 9; and

FIG. 11 is a view illustrating a cross-section taken along line F11-F11 of a structure illustrated in FIG. 5.

### DETAILED DESCRIPTION OF THE INVENTION

Hereinafter, an embodiment will be described with reference to the drawings. In the following description, constitutions having the same or similar functions are denoted by the same reference numbers. Redundant descriptions of these constitutions may be omitted. The constitutions to be described below do not limit the scope of the embodiment.

In the present disclosure, terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). “Orthogonal” may include a case of “substantially orthogonal”. “The same” may include a case of “substantially the same”.

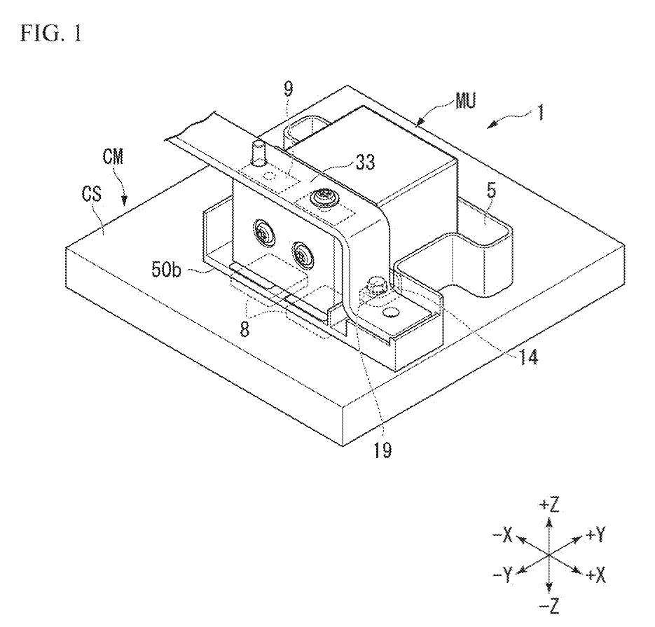

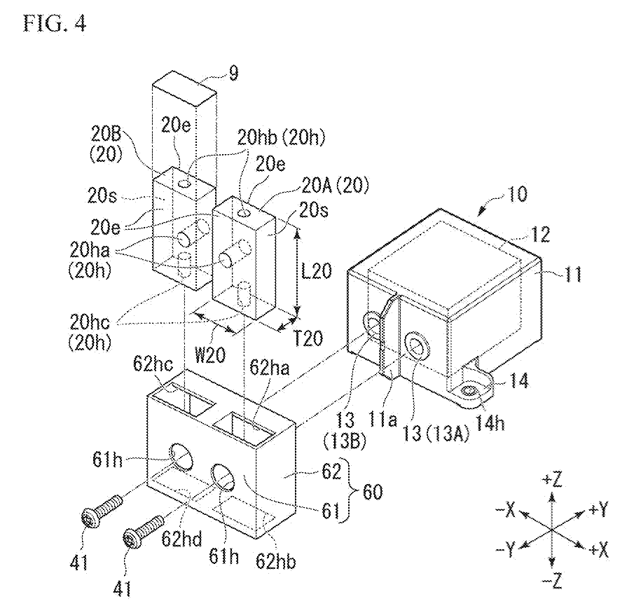

In the present disclosure, a +X direction, a -X direction, a +Y direction, a -Y direction, a +Z direction, and a -Z direction are defined as follows. The +Y direction is, for example, a direction in which an attachment hole 20h of a heat storage member 20A to be described later is open toward a terminal 13A of an electronic component 10 to be described later (see FIG. 1). The -Y direction is a direction opposite to the +Y direction. Hereinafter, the +Y direction and the -Y direction are simply referred to as “Y direction” in a case where the +Y direction and the -Y direction are not distinguished from each other. The +X direction and the -X direction are directions intersecting (for example, orthogonal to) the Y direction. The +X direction is, for example, a direction from a terminal 13B of the electronic component 10 to be described later toward the terminal 13A (See FIG. 4). The -X direction is a direction opposite to the +X direction. Hereinafter, the +X direction and the -X direction are simply referred to as “X direction” in a case where the +X direction and the -X direction are not distinguished from each other. The +Z direction and the -Z direction are directions intersecting (for example, orthogonal to) the X direction and the Y direction. The +Z direction is one direction of the Z direction. The -Z direction is a direction opposite to the +Z direction. Hereinafter, in a case where the +Z direction and the -Z direction are not distinguished, the directions will be simply referred to as “Z direction”. The Y direction is an example of a “first direction”. The Z direction is an example of a “third direction”. The X direction is an example of a “second direction”.

Hereinafter, in a case where the X direction and the Y direction are not distinguished, the directions may be referred to as a “horizontal direction”. Hereinafter, the Z direction may be referred to as a “vertical direction”. Hereinafter, the +Z direction side may be referred to as “upper”, and the -Z direction side may be referred to as “lower”. However, these expressions are expressions for convenience of description, and do not limit a gravity direction of an electrical connection unit 1 (an installation orientation of the electrical connection unit 1).

### 1. Constitution of electrical connection unit

FIG. 1 is a perspective view illustrating an electrical connection unit 1 of a first embodiment. The electrical connection unit 1 is, for example, an in-vehicle device mounted on a vehicle such as an electric vehicle (EV), a hybrid electric vehicle (HEV), or a plug-in hybrid electric vehicle (PHEV). For example, the electrical connection unit 1 may be referred to as an “electrical connection box” or a “junction box”. However, the electrical connection unit 1 is not limited to a box-shaped device. The electrical connection unit 1 is disposed in contact with an external cooling member CM (see FIG. 1). The external cooling member CM may be, for example, a water jacket. The external cooling member CM receives heat from the electrical connection unit 1 via the cooling surface CS of the cooling member CM, and performs cooling of the electrical connection unit 1.

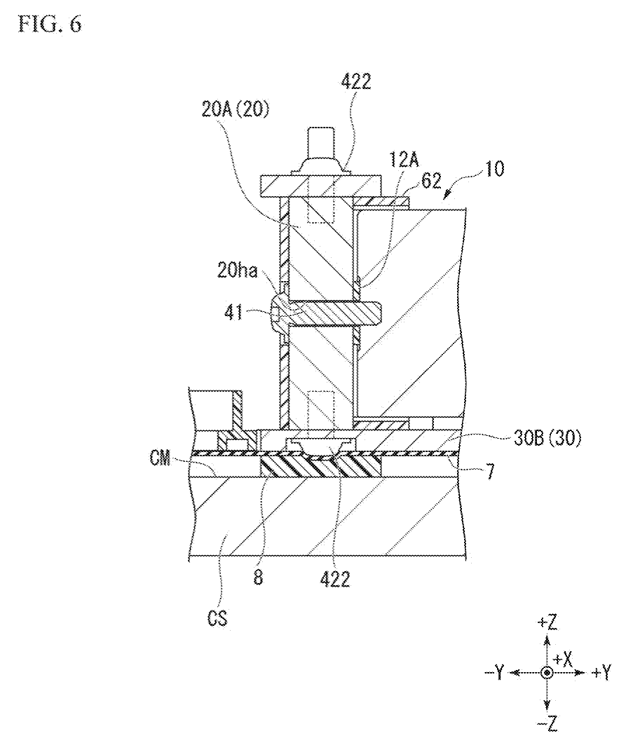

The electrical connection unit 1 includes, for example, a housing 5, a main body MU, an insulation sheet 7 (see FIG. 6), a plurality of heat transfer members 8, and an insulator 9.

### 2. Housing

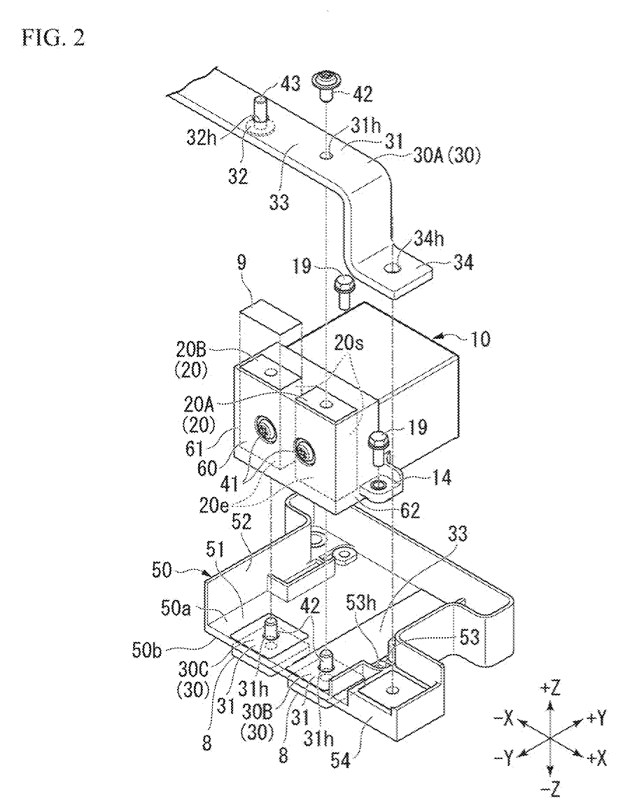

The housing 5 is a member forming the exterior of the electrical connection unit 1. The housing 5 is made of, for example, a synthetic resin and has an insulating property. The housing 5 accommodates the main body MU. The housing 5 has an insulating base member 50 (see FIG. 2). The base member 50 covers at least a part of the main body MU from the-Z direction side. The base member 50 is open on the +Z direction side. The housing 5 may further include a cover that covers the base member 50 from the +Z direction as necessary.

### 2.1 Base member

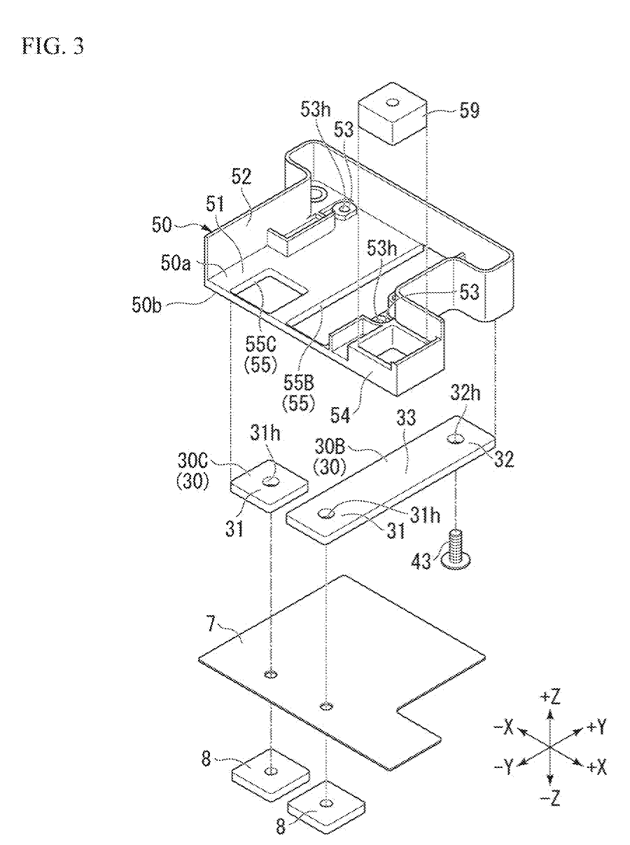

First, the base member 50 will be described with reference to FIGS. 2 and 3. The base member 50 is a support member that supports the electronic component 10 and/or a bus bar 30 (to be described later). The base member 50 in the present embodiment can fix the bus bar 30 via an insert nut 59 (see FIG. 3) accommodated in a fixing portion 53 (to be described later). The base member 50 in the present embodiment indirectly supports the electronic component 10 via a heat storage member 20 (to be described later) overlapping the bus bar 30 accommodated in an accommodation portion 55 (to be described later) in the Z direction. The base member 50 supports a plurality of the bus bars 30 by the accommodation portion 55.

FIG. 2 is an exploded perspective view illustrating the electrical connection unit 1. FIG. 3 is a partially exploded perspective view illustrating the electrical connection unit 1. The base member 50 includes, for example, a planar portion 51, a wall portion 52, a fixing portion 53, and a pedestal portion 54.

### Planar portion

The planar portion 51 is a portion formed in a plate shape in the base member 50. The planar portion 51 has a plate shape extending in the horizontal direction. The planar portion 51 forms a main portion of the base member 50. The planar portion 51 forms a base portion (insulation base portion) of the base member 50.

The planar portion 51 has a first surface 50a and a second surface 50b. The first surface 50a is a surface facing in the +Z direction. The first surface 50a is a plane extending in the horizontal direction. The first surface 50a faces the electronic component 10. The second surface 50b is located on the side opposite to the first surface 50a. The second surface 50b is a surface facing in the -Z direction. The second surface 50b is a plane extending in the horizontal direction. The second surface 50b faces the external cooling member CM (see FIG. 1). The thickness direction (plate thickness direction) of the planar portion 51 is the Z direction.

The planar portion 51 has, for example, a plurality of accommodation portions 55 in which the bus bar 30 is accommodated. The plurality of accommodation portions 55 are formed apart from each other in the horizontal direction. Each of the accommodation portions 55 is, for example, a through-hole penetrating the planar portion 51 in the Z direction. With this constitution, the bus bar 30 accommodated in the accommodation portion 55 is exposed in the -Z direction. The planar portion 51 in the present embodiment has, for example, two accommodation portions 55.

Each accommodation portion 55 has an outer shape corresponding to the shape of the bus bar 30 to be accommodated when viewed from the Z direction. The plurality of accommodation portions 55 include, for example, two accommodation portions 55B and 55C. The accommodation portion 55B is provided to correspond to a bus bar 30B to be described later, and accommodates at least a part of the bus bar 30B. The accommodation portion 55C is provided to correspond to a bus bar 30C to be described later, and accommodates at least a part of the bus bar 30C. Each of the bus bars 30B and 30C accommodated in the accommodation portion 55 is accommodated in a state of being exposed from the accommodation portion 55 toward the -Z direction.

In the present embodiment, the bus bars 30B and 30C and the base member 50 are integrated by insert molding. Each of the bus bars 30B and 30C is integrated with the base member 50 without using a fastening member such as a screw or a bolt. Instead of the above-described example, each of the bus bars 30B and 30C may be pressed into the accommodation portion 55. In this way, each of the bus bars 30B and 30C is supported by base member 50.

### Wall portion

The wall portion 52 extends in the +Z direction from the edge of the planar portion 51 in the horizontal direction. In the horizontal direction, the wall portion 52 faces the electronic component 10.

### Fixing portion

The fixing portion 53 is a portion for fixing the electronic component 10. The fixing portion 53 is a boss protruding from the planar portion 51 in the +Z direction. The fixing portion 53 has, for example, an attachment hole 53h into which a fastening member 19 is inserted. For example, the inner circumferential surface of the attachment hole 53h has screw grooves. For example, the attachment hole 53h is a bottomed hole provided in the fixing portion 53. The fastening member 19 is inserted into the attachment hole 53h along the Z direction. The fastening member 19 is engaged with the attachment hole 53h through an attachment hole 14h (to be described later). Instead of the above-described example, the attachment hole 53h may be a through-hole provided in the fixing portion 53.

### Pedestal portion

A pedestal portion 54 protrudes from the planar portion 51 in the +Z direction. The pedestal portion 54 has, for example, a through-hole or a recess in which the insert nut 59 is accommodated. The bus bar 30 (for example, a bus bar 30A) forming the energization path separated from a plurality of bus bars 30 accommodated in the accommodation portion 55 in the +Z direction can be fixed by the fastening member (for example, a screw or a bolt) engaged with the insert nut 59.

### 3. Main body

The main body MU is a portion that performs a main function (for example, switching of electrical connection states or overcurrent protection) of the electrical connection unit 1. The main body MU includes, for example, one electronic component 10, a plurality of heat storage members 20 (see FIG. 4), a plurality of bus bars 30, a plurality of fastening members 41, a plurality of fastening members 42, and an insulation portion 60.

In the present disclosure, a first side and a second side are defined as follows.

One side (for example, +Z direction side) in a direction (for example, in the Z direction) intersecting a direction (for example, the Y direction) in which an attachment hole 20h of the heat storage member 20A faces toward the terminal 13A of the electronic component 10 to be described later is a first side, and the other side (for example, -Z direction side) in the intersecting direction is a second side. The intersecting direction intersects a direction (for example, the X direction) in which the terminal 13A and the terminal 13B to be described later are arranged.

### 3.1. Electronic component

The electronic component 10 will be described with reference to FIGS. 2 and 4. The electronic component 10 is an electronic component mounted in accordance with a function required for the main body MU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. However, the type of electronic component 10 is not limited to the above example. The electronic component 10 is, for example, a heat generating component that generates heat at the time of energization.

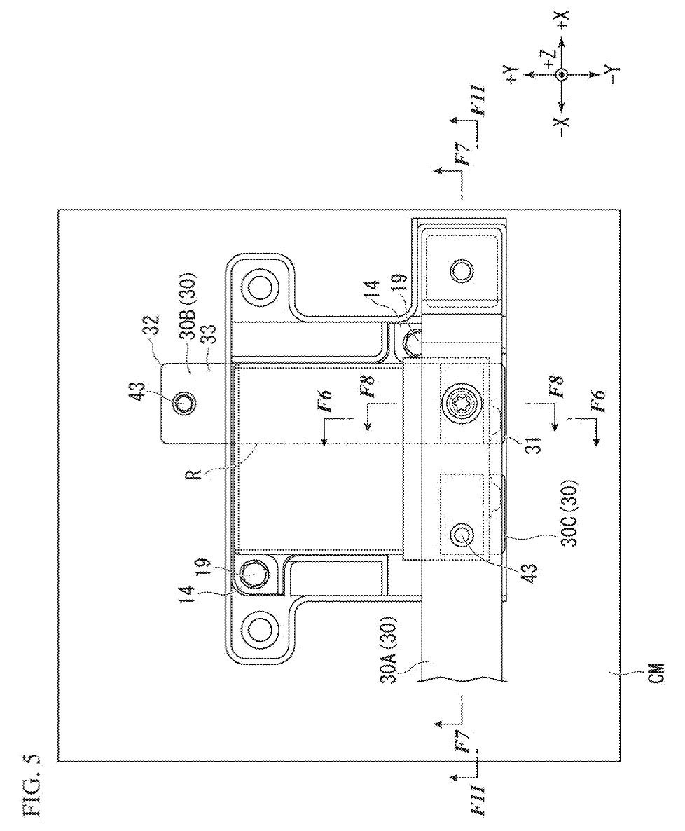

FIG. 4 is a partially exploded perspective view illustrating the electrical connection unit 1. The electronic component 10 includes, for example, a case 11, a component body 12, a plurality of terminals 13, and a plurality of attachment portions 14 (only one is illustrated in FIG. 4., and two are illustrated in FIG. 5).

### Case

The case 11 is an outer member that forms most of the outer shape of the electronic component 10. The case 11 is made of, for example, a synthetic resin and has an insulating property. The case 11 accommodates the component body 12. The case 11 and the component body 12 may be integrally formed.

In the present embodiment, the case 11 has an insulation rib 11a protruding in the horizontal direction (for example, the -Y direction) and extending in the Z direction. The insulation rib 11a has, for example, a plate shape formed in the Y direction and the Z direction. The insulation rib 11a extends, for example, over the entire length of the case 11 in the Z direction. The insulation rib 11a is disposed between the plurality of terminals 13 (a terminal 13A and a terminal 13B to be described later). The insulation rib 11a electrically insulates the terminal 13A from the terminal 13B. In the present embodiment, a part of the insulation rib 11a is disposed between two heat storage members 20 (heat storage members 20A and 20B) to be described later. For example, the insulation rib 11a electrically insulates at least a part of the two heat storage members 20 from each other.

### Component body

The component body 12 is a portion that performs a main function of the electronic component 10. For example, in a case where the electronic component 10 is a relay, the component body 12 includes a switch (for example, a contact) that switches between a conductive state and a non-conductive state. For example, in a case where the electronic component 10 is a fuse, the component body 12 includes a fusion portion that is fused when an overcurrent flows. For example, in a case where the electronic component 10 is a capacitor, the component body 12 includes a portion that stores electric charge.

### Terminal

Each of the terminals 13 is an electrical connection portion exposed to the outside of the case 11. The terminal 13 is electrically connected to the component body 12 inside the case 11. In the present embodiment, the electronic component 10 includes the terminal 13A and the terminal 13B as the plurality of terminals 13. One of the terminal 13A and the terminal 13B is a terminal on the positive electrode side. The other of the terminal 13A and the terminal 13B is a terminal on the negative electrode side. One of the terminal 13A and the terminal 13B is an example of a “first terminal”. The other of the terminal 13A and the terminal 13B is an example of a “second terminal”.

In the present embodiment, the terminal 13A and the terminal 13B are provided at one end of the electronic component 10 in the horizontal direction (for example, the Y direction). The terminal 13A and the terminal 13B are arranged in the horizontal direction (for example, the X direction). Each of the terminal 13A and the terminal 13B is directed in the horizontal direction (for example, the Y direction).

Each terminal 13 has an attachment hole 13h (not illustrated) into which a fastening member 41 (for example, a screw or a bolt) to be described later is inserted. The attachment hole 13h is open in the horizontal direction (for example, the -Y direction). The inner circumferential surface of the attachment hole 13h of the electronic component 10 has screw grooves. The attachment hole 13h is a bottomed hole provided in the electronic component 10.

In the present disclosure, the “attachment hole” is not limited to a hole having screw grooves, and may be a hole having no screw groove. In the present disclosure, the “attachment hole” may be a through-hole or the like penetrating the terminal 13 in the plate thickness direction of the terminal 13 in a case where the terminal 13 has a plate shape.

### Attachment portion

Each of the attachment portions 14 is a portion for fixing the electronic component 10. For example, the attachment portion 14 overlaps the fixing portion 53 of the base member 50 in the Z direction (see FIG. 2). The attachment portion 14 has an attachment hole 14h into which the fastening member 19 (for example, a screw or a bolt) is inserted. The attachment hole 14h is open in the Z direction. The attachment hole 14h is an insertion hole through which the fastening member 19 passes. The fastening member 19 is engaged with the attachment hole 53h through the attachment hole 14h.

### 3.2. Heat storage member

Next, the heat storage member 20 will be described with reference to FIG. 4 again. The heat storage member 20 is a component that electrically and thermally connects a first connection target and a second connection target. For example, the heat storage member 20 stores (absorbs) at least a part of heat generated by the first connection target and/or the second connection target. The heat storage member 20 is made of, for example, copper, a copper alloy, aluminum, or an aluminum alloy, but is not limited to these examples.

The first connection target is the electronic component 10. The second connection target is the bus bar 30.

The heat storage member 20 may electrically and thermally connect the first connection target, the second connection target, and a third connection target. For example, the third connection target is any one of the electronic component 10, the heat storage member 20, the bus bar 30, or a bus bar for external connection. The second connection target and the third connection target in the present embodiment are both bus bars 30. The bus bar for external connection is a bus bar for connecting an external device. The bus bar for external connection has at least a first connection portion 31 (to be described later).

The heat storage member 20 is disposed in an upright orientation in the Z direction. The heat storage member 20 is, for example, a rectangular parallelepiped metal block along the Z direction. The heat storage member 20 has two end surfaces 20e and a peripheral surface 20s. The end surfaces 20e are surfaces located at both ends of the heat storage member 20 in the Y direction and facing the Y direction. When viewed from the Y direction, each of the end surfaces 20e has a rectangular shape. The peripheral surface 20s is a surface extending along the Y direction from the peripheral edge of one of the two end surfaces 20e of the heat storage member 20. The heat storage member 20 is adjacent to the terminal 13 in the horizontal direction (for example, the Y direction).

The heat storage member 20 has a plurality of attachment holes 20h. Each connection target (for example, the first connection target, the second connection target, and the third connection target) is physically connected to the heat storage member 20 through the attachment hole 20h. The number of connection targets connectable to the heat storage member 20 is determined by the number of holes included in a plurality of attachment holes 20h. In the present embodiment, the heat storage member 20 includes, as the plurality of attachment holes 20h, an attachment hole 20ha, an attachment hole 20hb, and an attachment hole 20hc. The heat storage member 20 in the present embodiment electrically and thermally connects the first connection target, the second connection target, and the third connection target.

In the present embodiment, the first connection target (for example, the electronic component 10) is connected to the attachment hole 20ha. The second connection target (for example, the bus bar 30A to be described later) is connected to the attachment hole 20hb. The third connection target (for example, the bus bar 30B to be described later) is connected to the attachment hole 20hc.

The attachment hole 20ha of the heat storage member 20 is open toward the terminal 13 in the Y direction. The attachment hole 20ha is an insertion hole through which the fastening member 41 passes. For example, attachment hole 20ha is a through-hole penetrating the heat storage member 20 in the Y direction.

For example, the attachment hole 20hb of the heat storage member 20 is located on the first side in the Z direction (for example, +Z direction side) and is open toward the first side in the Z direction. The attachment hole 20hb in the present embodiment is open toward an attachment hole 31h of the first connection portion 31 of the bus bar 30A in the Z direction. The attachment hole 20hb is an insertion hole through which each of the fastening members 42 passes. For example, the inner circumferential surface of the attachment hole 20hb has screw grooves. For example, the attachment hole 20hb in the present embodiment is a bottomed hole provided in the heat storage member 20. The fastening member 42 is inserted into the attachment hole 20hb along the Z direction.

For example, the attachment hole 20hc of the heat storage member 20 is located on the second side in the Z direction (for example, -Z direction side) and is open toward the second side in the Z direction. The attachment hole 20hc in the present embodiment is open toward the attachment hole 31h of the bus bar 30B or the attachment hole 31h of the bus bar 30C in the Z direction. The attachment hole 20hc is an insertion hole through which each of the fastening members 42 passes. For example, the inner circumferential surface of the attachment hole 20hc has screw grooves. For example, the attachment hole 20hc in the present embodiment is a bottomed hole provided in the heat storage member 20. The fastening member 42 is inserted into the attachment hole 20hc along the Z direction.

Next, the arrangement of a plurality of heat storage members 20 will be described.

The main body MU includes a heat storage member 20A and a heat storage member 20B as the plurality of heat storage members 20 (two heat storage members are illustrated in FIG. 4). One of the heat storage member 20A and the heat storage member 20B is an example of a “first metal block”. The “first metal block” is adjacent to the “first terminal”. The other of the heat storage member 20A and the heat storage member 20B is an example of a “second metal block”. The “second metal block” is adjacent to the “second terminal”. Hereinafter, in a case where the heat storage member 20A and the heat storage member 20B are not distinguished from each other, the heat storage member 20A and the heat storage member 20B are simply referred to as “heat storage member 20”.

For example, the first connection target of the heat storage member 20A in the present embodiment is the electronic component 10. The second connection target of the heat storage member 20A in the present embodiment is the bus bar 30A. For example, the third connection target of the heat storage member 20A in the present embodiment is the bus bar 30B.

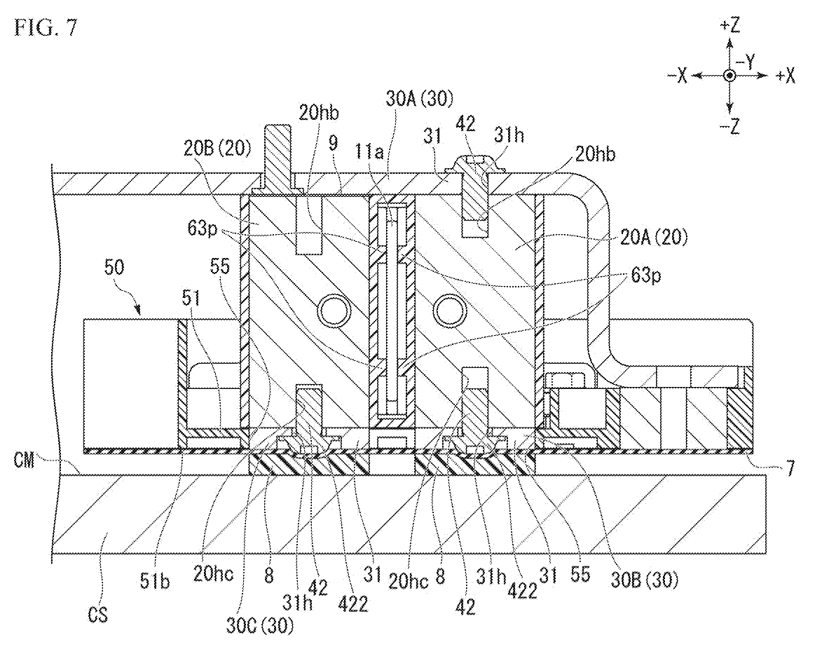

For example, the first connection target of the heat storage member 20B in the present embodiment is the electronic component 10. The third connection target of the heat storage member 20B in the present embodiment is the bus bar 30C. That is, in the heat storage member 20B in the present embodiment, the second connection target is not connected to the attachment hole 20hb (see FIG. 7).

For example, the heat storage member 20A is adjacent to the terminal 13A in the Y direction. The heat storage member 20A is adjacent to the first connection portion 31 of the bus bar 30A (to be described later) in the Z direction. The heat storage member 20A is adjacent to the first connection portion 31 of the bus bar 30B (to be described later) in the Z direction.

For example, the heat storage member 20B is adjacent to the terminal 13B in the Y direction. The heat storage member 20B is adjacent to the first connection portion 31 of the bus bar 30C (to be described later) in the Z direction.

A length L20 of the heat storage member 20 in the Z direction and a width W20 of the heat storage member 20 in the X direction are greater than a thickness T20 of the heat storage member 20 in the Y direction. The length L20 of the heat storage member 20 in the Z direction is greater than the width W20 of the heat storage member 20 in the X direction.

### 3.3 Bus bar

The bus bar 30 will be described with reference to FIGS. 2 and 3 again. The bus bar 30 is a routing member that electrically connects the electronic component 10 included in the main body MU. The bus bar 30 is made of metal (for example, made of copper, made of a copper alloy, made of aluminum, or made of an aluminum alloy) and has conductivity.

The bus bar 30 has at least the first connection portion 31. The bus bar 30 may further have a second connection portion 32 and an extension portion 33. In the present embodiment, the entire bus bar 30 including the first connection portion 31, the second connection portion 32, and the extension portion 33 is formed of one plate member. The bus bar 30 may be formed by, for example, bending the one plate member.

### First connection portion

The first connection portion 31 is a portion connected to the heat storage member 20. The first connection portion 31 is located in the middle of the bus bar 30 or at a first end of the bus bar 30. The first connection portion 31 is, for example, a plate portion extending along the X direction and the Y direction.

The first connection portion 31 has an attachment hole 31h into which the fastening member 42 is inserted. The attachment hole 31h does not have, for example, screw grooves. The attachment hole 31h is, for example, a through-hole penetrating the first connection portion 31 in the thickness direction (plate thickness direction) of the first connection portion 31. The first connection portion 31 includes a portion overlapping the heat storage member 20 when viewed from the plate thickness direction of the first connection portion 31.

### Second connection portion

The second connection portion 32 is a portion connected to any one of the electronic component 10, the heat storage member 20, the bus bar 30, or the bus bar for external connection. The second connection portion 32 is located in the middle of the bus bar 30 or at a second end of the bus bar 30. The second connection portion 32 is a plate portion.

The second connection portion 32 has the attachment hole 32h into which a fastening member 43 (for example, a screw or a bolt) is inserted. The attachment hole 32h does not have, for example, screw grooves. The attachment hole 32h is, for example, a through-hole penetrating the second connection portion 32 in the thickness direction (plate thickness direction) of the second connection portion 32. The fastening member 43 is inserted into the attachment hole 32h. The second connection portion 32 includes a portion overlapping the fastening member 43 when viewed from the plate thickness direction of the second connection portion 32.

### Extension portion

The extension portion 33 is provided between the first connection portion 31 and the second connection portion 32. The extension portion 33 extends from the first connection portion 31 toward the second connection portion 32. The extension portion 33 extends between the first connection portion 31 and the second connection portion 32. The extension portion 33 connects the first connection portion 31 and the second connection portion 32. A part of the extension portion 33 may be bent.

Next, the arrangement of a plurality of bus bars 30 will be described.

Hereinafter, three bus bars 30 electrically connected to the electronic component 10 via a plurality of heat storage members 20 will be described. The main body MU includes, as the plurality of bus bars 30, the bus bar 30A, the bus bar 30B, and the bus bar 30C.

### Bus bar 30A

The bus bar 30A has a first connection portion 31, a second connection portion 32, an extension portion 33, and a fixing portion 34. The fixing portion 34 is a plate portion that can be electrically connected to the insert nut 59. The fixing portion 34 has an attachment hole 34h into which a fastening member (for example, a screw or a bolt) engaged with the insert nut 59 is inserted. The attachment hole 34h is, for example, a through-hole penetrating the fixing portion 34 in the thickness direction of the fixing portion 34.

The first connection portion 31 of the bus bar 30A is a plate portion extending along the X direction and the Y direction. The first connection portion 31 of the bus bar 30A faces, for example, the heat storage member 20A in the Z direction. For example, the bus bar 30A faces the heat storage member 20A from the first side (for example, +Z direction side) in the Z direction. The bus bar 30A in the present embodiment further faces the heat storage member 20B from the first side in the Z direction. At this time, the attachment hole 31h of the first connection portion 31 of the bus bar 30A is open in the Z direction.

The attachment hole 31h of the first connection portion 31 of the bus bar 30A overlaps the attachment hole 20hb of the heat storage member 20A in the Z direction. The fastening member 42 is inserted into the attachment hole 31h of the first connection portion 31 along the Z direction from the +Z direction.

The second connection portion 32 of the bus bar 30A is, for example, a plate portion extending along the X direction and the Y direction. In the bus bar 30A, the second connection portion 32 is disposed on the -X direction side with respect to the first connection portion 31. The attachment hole 32h of the second connection portion 32 of the bus bar 30A faces the heat storage member 20B in the Z direction. The attachment hole 31h of the first connection portion 31 of the bus bar 30A may overlap the attachment hole 20hb of the heat storage member 20B in the Z direction.

The fastening member 43 (for example, a screw or a bolt) is inserted into the attachment hole 32h of the second connection portion 32 of the bus bar 30A along the Z direction. In the bus bar 30A, an engagement member (for example, a nut) can be engaged with the distal portion of the fastening member 43 that has passed through the attachment hole 32h. In the present embodiment, in a state in which the fastening member 43 is inserted into the bus bar 30A in advance from the -Z direction side, the bus bar 30A faces the heat storage member 20A and the heat storage member 20B from the first side in the Z direction. With this constitution, any one of the electronic component 10, the heat storage member 20, the bus bar 30, or the bus bar for external connection can be electrically connected to the second connection portion 32 of the bus bar 30A.

The fixing portion 34 is disposed along the horizontal direction in a state of being placed on the insert nut 59 accommodated in the pedestal portion 54 of the base member 50. For example, the fixing portion 34 may be fixed to the insert nut 59 accommodated in the pedestal portion 54 using the above-described fastening member. With this constitution, the bus bar 30A can be fixed to the base member 50 via the insert nut 59.

### Bus bar 30B

The bus bar 30B has a first connection portion 31, a second connection portion 32, and an extension portion 33. The first connection portion 31 of the bus bar 30B is a plate portion extending along the X direction and the Y direction. Here, among a plurality of bus bars 30, two bus bars 30 (bus bars 30A and 30B) are disposed such that the first side and the second side are separated from each other in the Z direction. As described above, the bus bar 30A is located on the first side in the Z direction with respect to the heat storage member 20A and the heat storage member 20B. On the other hand, the bus bar 30B is located on the second side (for example, -Z direction side) in the Z direction with respect to the heat storage member 20A. The first connection portion 31 of the bus bar 30B faces, for example, the heat storage member 20A in the Z direction. For example, the bus bar 30B faces the heat storage member 20A from the second side in the Z direction. At this time, the attachment hole 31h of the first connection portion 31 of the bus bar 30B is open in the Z direction.

The attachment hole 31h of the first connection portion 31 of the bus bar 30B overlaps the attachment hole 20hc of the heat storage member 20A in the Z direction. The fastening member 42 is inserted into the attachment hole 31h of the first connection portion 31 along the Z direction from the -Z direction.

The second connection portion 32 of the bus bar 30B is, for example, a plate portion extending along the X direction and the Y direction. In the bus bar 30B, the second connection portion 32 is disposed on the +Y direction side with respect to the first connection portion 31. In the bus bar 30B, the second connection portion 32 and the first connection portion 31 are located on substantially the same plane. A part (for example, a part of the extension portion 33 and the second connection portion 32 illustrated in FIG. 2) of the bus bar 30B is supported by the accommodation portion 55.

In the present embodiment, the first connection portion 31 of the bus bar 30B is disposed along the horizontal direction in a state of being accommodated in the accommodation portion 55 of the base member 50. In the bus bar 30B, at least a part of the extension portion 33 connecting the first connection portion 31 and the second connection portion 32 extends in the horizontal direction in the accommodation portion 55 (see FIGS. 3 and 5). A horizontal energization path is formed in the accommodation portion 55 of the planar portion 51. Since at least a part of the extension portion 33 is accommodated in the accommodation portion 55, the bus bar 30B extends over both sides of a region R through the region R overlapping the electronic component 10 when viewed from the Z direction (see FIG. 5).

The fastening member 43 (for example, a screw or a bolt) is inserted into the attachment hole 32h of the second connection portion 32 of the bus bar 30B along the Z direction (see FIG. 5). The engagement member (for example, a nut) can be engaged with the distal portion of the fastening member 43 that has passed through the attachment hole 32h of the second connection portion 32. With this constitution, any one of the electronic component 10, the heat storage member 20, the bus bar 30, or the bus bar for external connection can be electrically connected to the second connection portion 32 of the bus bar 30B.

### Bus bar 30C

The bus bar 30C has the first connection portion 31.

The first connection portion 31 of the bus bar 30C is a plate portion extending along the X direction and the Y direction. The first connection portion 31 of the bus bar 30C faces, for example, the heat storage member 20B in the Z direction. For example, the bus bar 30C faces the heat storage member 20B from the second side (for example, -Z direction side) in the Z direction. At this time, the attachment hole 31h of the first connection portion 31 of the bus bar 30C is open in the Z direction.

The attachment hole 31h of the first connection portion 31 of the bus bar 30C overlaps the attachment hole 20hc of the heat storage member 20B in the Z direction. The fastening member 42 is inserted into the attachment hole 31h of the first connection portion 31 along the Z direction from the -Z direction.

In the present embodiment, the first connection portion 31 of the bus bar 30C is disposed along the horizontal direction in a state of being supported by the accommodation portion 55 of the base member 50. The two bus bars 30B and 30C are disposed within the accommodation portions 55 and arranged at intervals in the horizontal direction. The two bus bars 30B and 30C are disposed on substantially the same plane. The two bus bars 30B and 30C are electrically insulated by the accommodation portion 55 of the planar portion 51 which is an insulation base portion.

Next, the fastening member 41 and the fastening member 42 will be described in detail.

The fastening member 41 is a component for fixing the terminal 13 (the terminal 13A or the terminal 13B) and the heat storage member 20 corresponding to the terminal 13. The fastening member 42 is a component for fixing the first connection portion 31 of the bus bar 30 and the heat storage member 20 corresponding to the first connection portion 31.

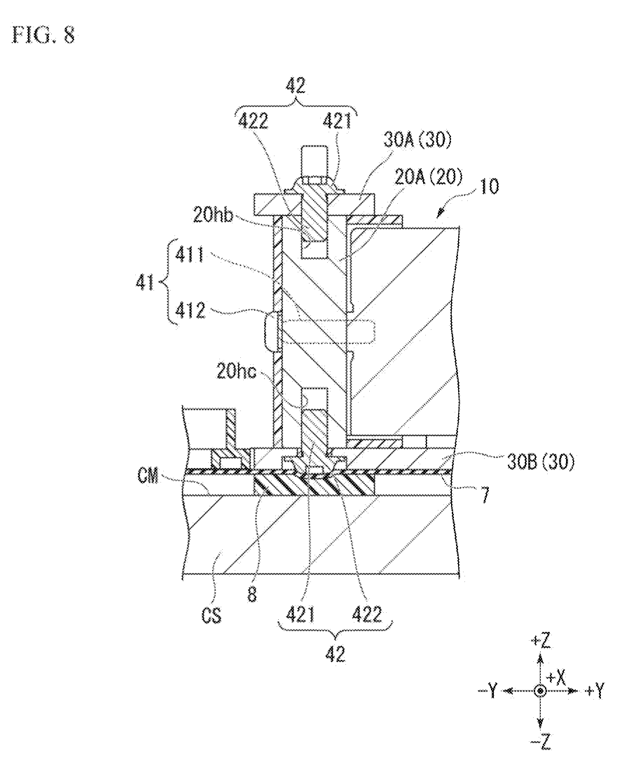

The fastening member 41 has a first shaft 411 passing through the attachment hole 20ha and a first head 412 located at one end of the first shaft 411 (see FIG. 8). The fastening member 42 has a second shaft 421 passing through the attachment hole 20hb or the attachment hole 20hc and a second head 422 located at one end of the second shaft 421 (see FIG. 8).

First, the attachment of the heat storage member 20A will be described with reference to FIG. 6. FIG. 6 is a cross-sectional view taken along line F6-F6 of the structure illustrated in FIG. 5.

The fastening member 41 inserted from the -Y direction passes through the attachment hole 20ha to connect the heat storage member 20A and the terminal 13A. With this constitution, the heat storage member 20A and the terminal 13A are electrically connected to each other. In addition, the electronic component 10 is thermally connected to the heat storage member 20A.

Next, each connection target connected to the heat storage member 20A will be described with reference to FIG. 7. FIG. 7 is a cross-sectional view taken along line F7-F7 of the structure illustrated in FIG. 5.

For example, the fastening member 42 inserted from the +Z direction passes through the attachment hole 31h and the attachment hole 20hb to connect the bus bar 30A and the heat storage member 20A. With this constitution, the first connection portion 31 of the bus bar 30A and the heat storage member 20A are physically and electrically connected to each other. In addition, the bus bar 30A is thermally connected to the heat storage member 20A. For example, the fastening member 42 inserted from the -Z direction passes through the attachment hole 31h and the attachment hole 20hc to connect the heat storage member 20A and the bus bar 30B. With this constitution, the first connection portion 31 of the bus bar 30B and the terminal 13A of the electronic component 10 are physically and electrically connected to each other. In addition, the bus bar 30B is thermally connected to the heat storage member 20A.

Next, the attachment of the heat storage member 20B will be described.

The fastening member 41 inserted from the -Z direction passes through the attachment hole 20ha to connect the heat storage member 20B and the terminal 13B. With this constitution, the heat storage member 20B and the terminal 13B are physically and electrically connected to each other. In addition, the bus bar 30C is thermally connected to the heat storage member 20B.

Next, each connection target connected to the heat storage member 20B will be described.

For example, the fastening member 42 passes through the attachment hole 31h and the attachment hole 20hc to connect the bus bar 30C and the heat storage member 20B. With this constitution, the first connection portion 31 of the bus bar 30C and the heat storage member 20B are physically and electrically connected to each other.

Next, a positional relationship between the fastening member 41 and the fastening member 42, which are fastened to the heat storage member 20, will be described with reference to FIG. 8. FIG. 8 is a cross-sectional view taken along line F8-F8 of the structure illustrated in FIG. 5.

For example, when viewed from the X direction, the distance between the electronic component 10 and the second shaft 421 in the Y direction is smaller than the distance between the electronic component 10 and the first head 412 in the Y direction.

### 4. Insulation portion

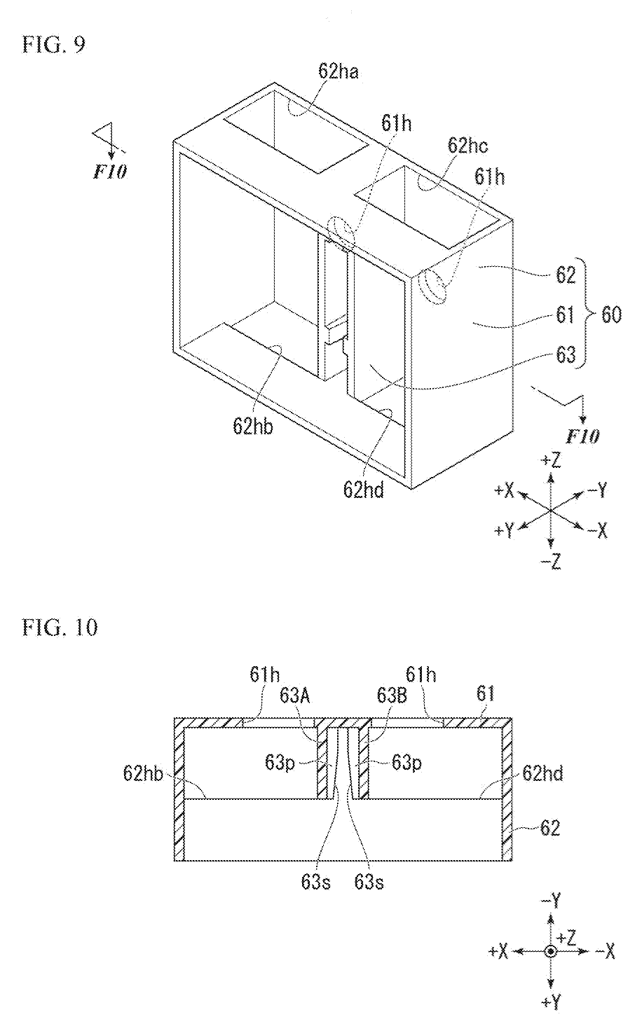

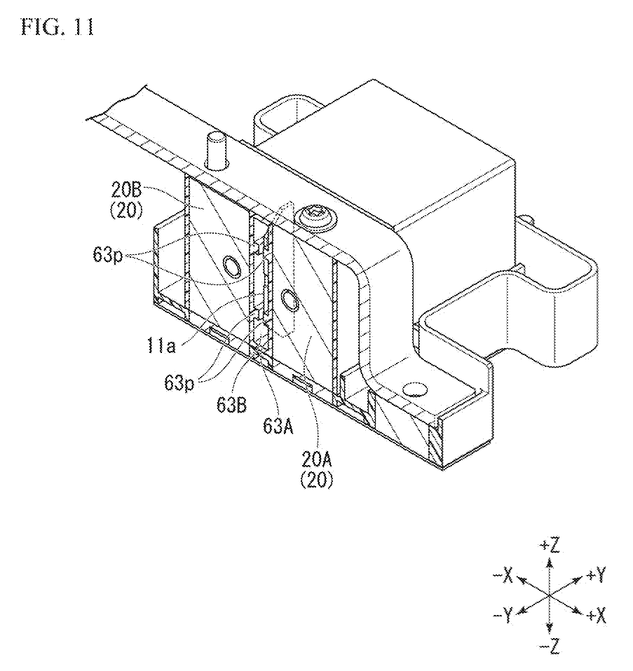

Next, the insulation portion 60 will be described with reference to FIGS. 4 and 9 to 11. FIG. 9 is a perspective view illustrating a part of the electrical connection unit 1. FIG. 10 is a cross-sectional view taken along line F10-F10 of the structure illustrated in FIG. 9. FIG. 11 is a view illustrating a cross-section taken along line F11-F11 of a structure illustrated in FIG. 5.

The insulation portion 60 is an insulation member for securing an insulation distance between the heat storage member 20A and the heat storage member 20B. For example, the insulation portion 60 contacts the insulation rib 11a of the electronic component 10 to secure the insulation distance between the heat storage member 20A and the heat storage member 20B. In the present embodiment, the insulation portion 60 is made of, for example, a synthetic resin and has an insulating property. The insulation portion 60 has a wall portion 61 and a peripheral wall portion 62. The insulation portion 60 may further have an inner wall portion 63 as necessary. The insulation portion 60 covers at least a part of the peripheral surface of the heat storage member 20 with the peripheral wall portion 62. In the present embodiment, the insulation portion 60 includes a plurality of (for example, two) inner wall portions 63, and the peripheral wall portion 62 covers at least a part of the peripheral surfaces of a plurality of (for example, two) heat storage members 20 (the heat storage members 20A and 20B).

The wall portion 61 has a plate shape extending along the Z direction and the X direction. The wall portion 61 overlaps the end surface 20e of the heat storage member 20A and the end surface 20e of the heat storage member 20B in the Y direction (see FIGS. 2 and 4). The wall portion 61 in the present embodiment faces the heat storage member 20A and the heat storage member 20B from the -Y direction side. The wall portion 61 has an insertion hole 61h into which the fastening member 41 is inserted. The insertion hole 61h is, for example, a through-hole penetrating the wall portion 61 in the thickness direction (plate thickness direction) of the wall portion 61.

The peripheral wall portion 62 extends in the Y direction from the peripheral edge of the wall portion 61. When viewed from a direction intersecting the Y direction (for example, in the X direction), the peripheral wall portion 62 covers the peripheral surface 20s of the heat storage member 20A and the peripheral surface 20s of the heat storage member 20B (see FIGS. 2 and 4). For example, the peripheral wall portion 62 of the present embodiment extends in the Y direction so as to overlap at least a part of the electronic component 10 when viewed from a direction intersecting the Y direction (for example, in the X direction) (see FIG. 2). In such a constitution, it is easy to align the insulation portion 60 with respect to the electronic component 10. The peripheral wall portion 62 may extend, for example, over the entire length of the case 11 in the Y direction.

The peripheral wall portion 62 has one or a plurality of insertion holes 62h that are open in the Z direction. In the present embodiment, the peripheral wall portion 62 includes, as the plurality of insertion holes 62h, an insertion hole 62ha, an insertion hole 62hb, an insertion hole 62hc, and an insertion hole 62hd. The insertion hole 62ha is an example of a “first insertion hole”. The insertion hole 62hb is an example of a “second insertion hole”. The insertion hole 62hc is an example of a “third insertion hole”. The insertion hole 62hd is an example of a “fourth insertion hole”. A modification example in which the peripheral wall portion 62 has one insertion hole 62h will be described later.

The insertion hole 62ha and the insertion hole 62hb are open in the Z direction toward the heat storage member 20A. The insertion hole 62ha of the peripheral wall portion 62 is located on the first side (for example, +Z direction side) in the Z direction. The insertion hole 62hb of the peripheral wall portion 62 is located on the second side (for example, -Z direction side) in the Z direction.

When viewed from the Z direction, the insertion hole 62ha and the insertion hole 62hb may overlap each other. In this case, the insertion hole 62ha and the insertion hole 62hb may communicate with each other. In the present embodiment, the insertion hole 62ha and the insertion hole 62hb communicate with each other to penetrate the peripheral wall portion 62 in the Z direction. The heat storage member 20A is pressed into the peripheral wall portion 62 through the insertion hole 62ha and the insertion hole 62hb. With this constitution, the insulation portion 60 and the heat storage member 20A are integrated. Instead of pressing into the heat storage member 20A, the heat storage member 20A may be formed integrally with the peripheral wall portion 62 of the insulation portion 60 by, for example, insert molding or another means after being inserted into the insertion hole 62h.

The insertion hole 62hc and the insertion hole 62hd are open in the Z direction toward the heat storage member 20B. The insertion hole 62hc of the peripheral wall portion 62 is located on the first side in the Z direction. The insertion hole 62hd of the peripheral wall portion 62 is located on the second side in the Z direction.

When viewed from the Z direction, the insertion hole 62hc and the insertion hole 62hd may overlap each other. In this case, the insertion hole 62hc and the insertion hole 62hd may communicate with each other. In the present embodiment, the insertion hole 62hc and the insertion hole 62hd communicate with each other to penetrate the peripheral wall portion 62 in the Z direction. The heat storage member 20B is pressed into the peripheral wall portion 62 through the insertion hole 62hc and the insertion hole 62hd. With this constitution, the insulation portion 60 and the heat storage member 20B are integrated. Instead of pressing into the heat storage member 20B, the heat storage member 20B may be formed integrally with the peripheral wall portion 62 of the insulation portion 60 by, for example, insert molding or another means after being inserted into the insertion hole 62h. In the present embodiment, the insulation portion 60 integrally holds the heat storage member 20A and the heat storage member 20B using the insertion hole 62h of the peripheral wall portion 62. Instead of the above-described example, the insulation portion 60 may integrally hold only one of the plurality of heat storage members 20.

In the present embodiment, in a state in which two heat storage members 20 (the heat storage members 20A and 20B) are integrated with the insulation portion 60, each of the heat storage members 20 is electrically connected to the terminal 13 using the fastening member 41 passing through the insertion holes 61h.

The inner wall portion 63 has a plate shape extending from the wall portion 61 along the Z direction and the Y direction. The inner wall portion 63 extends from one end to the other end of the peripheral wall portion in the Z direction. The inner wall portion 63 and the insulation rib 11a insulate a plurality of terminals 13 (the terminal 13A and the terminal 13B) from each other. In the present embodiment, the insulation portion 60 includes an inner wall portion 63A and an inner wall portion 63B as a plurality of inner wall portions 63. The inner wall portion 63A is an example of a “first inner wall portion”. The inner wall portion 63B is an example of a “second inner wall portion”.

The inner wall portion 63 of the insulation portion 60 is disposed between the plurality of terminals 13 (the terminal 13A and the terminal 13B). For example, two inner wall portions 63 (the inner wall portions 63A and 63B) are disposed between the terminal 13A and the terminal 13B. Each inner wall portion 63 electrically insulates the terminal 13A from the terminal 13B.

For example, the inner wall portion 63A is located on the terminal 13A side (or the heat storage member 20A side) of the two inner wall portions (the inner wall portions 63A and 63B) of the insulation portion 60 (see FIG. 11). The inner wall portion 63B is located on the terminal 13B side (or the heat storage member 20B side) of the two inner wall portions (the inner wall portions 63A and 63B) of the insulation portion 60 (see FIG. 11).

The inner wall portion 63A sandwiches the insulation rib 11a with the inner wall portion 63B. The inner wall portion 63A has a protrusion 63p protruding toward the inner wall portion 63B on a surface facing the inner wall portion 63B. The inner wall portion 63B has a protrusion 63p protruding toward the inner wall portion 63A on a surface facing the inner wall portion 63A.

The protrusion 63p has an inclined surface 63s. The inclined surface 63s is inclined downward from one end of the protrusion 63p toward the insulation rib 11a of the electronic component 10. The inclined surface 63s in the present embodiment is inclined downward from one end of the protrusion 63p toward the +Y direction. The insulation rib 11a is guided between the two inclined surfaces 63s facing each other. After the insulation rib 11a is guided, the protrusion 63p of the inner wall portion 63A sandwiches the insulation rib 11a with the protrusion 63p of the inner wall portion 63B (see FIGS. 7 and 11).

### 5. Insulation sheet and heat transfer member

Next, the insulation sheet 7, the heat transfer member 8, and the insulator 9 will be described with reference to FIGS. 6 to 8 again.

### 5.1 Insulation sheet

The insulation sheet 7 is an insulation member for insulating the bus bar 30 (bus bar 30B or 30C) accommodated in the accommodation portion 55 while facing the external cooling member CM. The insulation sheet 7 has a sheet shape formed in the horizontal direction. The insulation sheet 7 is made of, for example, a synthetic resin such as polyester or polyimide, and has an insulating property.

The insulation sheet 7 has an outer shape corresponding to the lower surface of the base member 50 (the second surface 50b of the planar portion 51) in the Z direction. The insulation sheet 7 is disposed between the bus bar 30 accommodated in the accommodation portion 55 and the cooling surface CS of the external cooling member CM. The heat transfer member 8 is disposed immediately below the insulation sheet 7 according to the present embodiment.

### 5.2. Heat transfer member

The heat transfer member 8 is a member for transferring the heat absorbed by the heat storage member 20 to the external cooling member CM. The heat transfer member 8 is, for example, a heat transfer sheet (for example, a thermally conductive silicone sheet) having elasticity. The heat transfer member 8 is made of a material having a higher thermal conductivity than the base member 50. However, the heat transfer member 8 is not limited to the above example, and may be a heat transfer member made of a thermally conductive gel or another material.

The heat transfer member 8 is disposed between the cooling surface CS of the external cooling member CM and the insulation sheet 7 in the Z direction. The heat transfer member 8 overlaps the bus bar 30 in the Z direction. Each of the plurality of heat transfer members 8 in the present embodiment overlaps, in the Z direction, the bus bar 30 (the bus bar 30B or the bus bar 30C) exposed from the accommodation portion 55 in the -Z direction. The heat transfer member 8 may have an outer shape corresponding to the lower surface of the base member 50 (the second surface 50b of the planar portion 51), and may cover each of the bus bars 30B and 30C and cover the lower surface.

A part of the heat transfer member 8 may be disposed at a position overlapping the second head 422 of the fastening member 42 in the Z direction, and may be in contact with the second head 422 of the fastening member 42. In this case, the heat transfer member 8 easily transfers the heat transferred from the terminal 13 of the electronic component 10 to the heat storage member 20 (heat storage member 20A or 20B) from the fastening member 42 to the external cooling member CM.

### 5.3. Insulator

As illustrated in FIG. 7 again, the insulator 9 is an insulation member for insulating the bus bar 30 (for example, the bus bar 30A) facing one heat storage member 20 (for example, the heat storage member 20A) in the Z direction and also facing the other heat storage member 20 (for example, the heat storage member 20B) in the same direction.

The insulator 9 overlaps the heat storage member 20 (for example, the heat storage member 20B) in the Z direction, and is disposed between the heat storage member 20 (for example, the heat storage member 20B) and the bus bar 30 (for example, bus bar 30A). With this constitution, the bus bar 30A facing the heat storage member 20A and the heat storage member 20B from the first side in the Z direction is electrically insulated from the heat storage member 20B by the insulator 9, and is thermally connected to the heat storage member 20B via the insulator 9.

For example, the insulator 9 has a sheet shape formed in the horizontal direction. The insulator 9 may be a heat transfer member having an insulating property. Instead of the above-described example, the insulator 9 may be an insulation coating of the bus bar 30 (for example, the bus bar 30A) provided between the bus bar 30 and the heat storage member 20 or an insulation coating of the heat storage member 20 (for example, the heat storage member 20B).

### 6. Advantages

In the present embodiment, the electrical connection unit 1 includes an electronic component 10 having a first terminal (for example, the terminal 13A), a first metal block (for example, the heat storage member 20A), and an insulation portion 60. The first metal block is adjacent to the first terminal in the first direction (for example, in the Y direction) and electrically connected to the first terminal. The first metal block has an end surface 20e in the first direction and a peripheral surface 20s extending from the peripheral edge of the end surface 20e in the first direction. The insulation portion 60 covers at least a part of the peripheral surface 20s.

In such a constitution, the insulation distance between the first metal block and another conductor is easily secured by the insulation portion 60 covering at least a part of the peripheral surface 20s of the first metal block. Thus, the insulation distance can be secured in the electrical connection unit 1.

In the present embodiment, the insulation portion 60 has a wall portion 61 overlapping the end surface 20e in the first direction and a peripheral wall portion 62 extending from the peripheral edge of the wall portion 61 in the first direction. The peripheral wall portion 62 covers the first metal block when viewed from the second direction (for example, in the X direction) intersecting the first direction.

In such a constitution, the first metal block adjacent to the first terminal is covered from the first direction by the wall portion 61 and the peripheral wall portion 62. The insulation portion 60 easily secures the insulation distance between the first metal block and another conductor. Thus, the insulation distance can be secured in the electrical connection unit 1.

In the present embodiment, the peripheral wall portion 62 has an insertion hole 62h (for example, the insertion holes 62ha and 62hb) that is open in a third direction (for example, in the Z direction) intersecting the first direction and the second direction. In such a constitution, when the first metal block is covered, the first metal block can be exposed outward through the peripheral wall portion 62. Since the heat is less likely to be confined in the insulation portion 60 covering the first metal block, it is easy to improve the thermal property of the electrical connection unit 1.

In the present embodiment, the insertion hole 62h includes a first insertion hole (for example, the insertion hole 62ha) and a second insertion hole (for example, the insertion hole 62hb). The first insertion hole is located on the first side (for example, +Z direction side) in the third direction. The second insertion hole is located on the second side (for example, -Z direction side) in the third direction. In such a constitution, the insulation distance can be secured by the peripheral wall portion 62 in a direction different from the third direction while securing the heat dissipation of the insulation portion 60 in the third direction.

In the present embodiment, the insulation portion 60 integrally holds the first metal block. In such a constitution, by integrating the insulation portion 60 and the first metal block, the first metal block is likely to be adjacent to the first terminal. Therefore, it is easy to improve the attachability of the first metal block.

In the present embodiment, the electrical connection unit 1 further includes a second metal block (for example, the heat storage member 20B). The electronic component 10 further has a second terminal (for example, the terminal 13B). The insulation portion 60 integrally holds the first metal block and the second metal block. The second metal block is adjacent to the second terminal in the first direction and connected to the second terminal. In such a constitution, by integrating the insulation portion 60, the first metal block, and the second metal block, the metal blocks (the first metal block and the second metal block) are easily arranged adjacent to a plurality of terminals (the first terminal and the second terminal). Therefore, the assemblability of the electrical connection unit 1 can be improved.

In the present embodiment, the electronic component 10 further has an insulation rib 11a that insulates the first terminal from the second terminal. The insulation portion 60 has a first inner wall portion (for example, the inner wall portion 63A) that insulates the first terminal from the second terminal together with the insulation rib 11a. In such a constitution, the insulation portion 60 can sufficiently secure the insulation distance between the first terminal and the second terminal together with the insulation rib 11a.

In the present embodiment, the insulation portion 60 further has a second inner wall portion (for example, the inner wall portion 63B). The first inner wall portion and the second inner wall portion are disposed between the first terminal and the second terminal. The first inner wall portion sandwiches the insulation rib 11a with the second inner wall portion. In such a constitution, the insulation distance between the first terminal and the second terminal can be sufficiently secured by the insulation rib 11a, the first inner wall portion, and the second inner wall portion. In addition, since the insulation rib 11a is sandwiched between the first inner wall portion and the second inner wall portion, the metal blocks (the first metal block and the second metal block) are easily arranged adjacent to a plurality of terminals (the first terminal and the second terminal), respectively.

### 7. Modification example

Next, several modification examples of the embodiment will be described below. A constitution other than that to be described below in each modification example is the same as the constitution of the embodiment.

### 7.1. First modification example

In the present modification example, the insulation portion 60 may be integrally formed as a single piece of member with one or both of the heat storage member 20A and the heat storage member 20B, for example, by insert molding. In such a constitution, the attachment work of the insulation portion 60 can be performed in association with the attachment work of at least one of the heat storage member 20A or the heat storage member 20B. With this constitution, it is possible to further improve the assemblability of the electrical connection unit 1.

### 7.2. Second modification example

In the embodiment, a part of a plurality of insertion holes 62h of the peripheral wall portion 62 may be closed. For example, in the insulation portion 60 in the present modification example, the peripheral wall portion 62 may not have the insertion hole 62hc. When viewed from the +Z direction, the heat storage member 20B is covered with the peripheral wall portion 62, and when viewed from the -Z direction, the heat storage member 20B is exposed from the peripheral wall portion 62. However, even in the case of the present modification example, at least a part of the peripheral surface 20s of the heat storage member 20B is covered with the peripheral wall portion 62 in the X direction. When the heat storage member 20B is covered with the peripheral wall portion 62 when viewed from the +Z direction, the insulator 9 that insulates the bus bar 30A facing the heat storage member 20B in the same direction while facing the heat storage member 20A in the Z direction may be omitted.

### 7.3. Third modification example

For example, the inner wall portion 63 disposed between the terminal 13A and the terminal 13B may be at least one of the plurality of inner wall portions 63. In this case, a cutout may be provided on one end surface of the inner wall portion facing the electronic component 10. The cutout is cut out to such an extent that the insulation rib 11a can be sandwiched.

### 7.4. Fourth modification example

For example, the insulation portion 60 may cover only any one of the plurality of heat storage members 20 (the heat storage members 20A and 20B). This is because, when one heat storage member 20 is covered, the insulation distance from another conductor is secured. In the case of the present modification example, the insulation portion 60 may not have the inner wall portion 63.

Several embodiments and modification examples have been described above. However, the embodiment and the modification examples are not limited to the examples described above. For example, a plurality of modification examples described above may be implemented in combination with each other.

### REFERENCE SIGNS LIST

1 Electrical connection unit
5 Housing
7 Insulation sheet
8 Heat transfer member
9 Insulator
10 Electronic component
11 Case
11a Insulation rib
12 Component body
13 Terminal
13A Terminal (first terminal)
13B terminal (first terminal and second terminal)
13h Attachment hole
14 Attachment portion
14h Attachment hole
19 Fastening member
20 Heat storage member
20A Heat storage member (first metal block)
20B Heat storage member (first metal block, second metal block)
20h Attachment hole
20ha Attachment hole
20hb Attachment hole
20hc Attachment hole
30 Bus bar
30A Bus bar
30B Bus bar
30C Bus bar
31 First connection portion
31h Attachment hole
32 Second connection portion
32h Attachment hole
33 Extension portion
34 Fixing portion
34h Attachment hole
41 Fastening member (first fastening member, fastening member)
411 First shaft
412 First head
42 Fastening member (second fastening member, fastening member)
421 Second shaft
422 Second head
43 Fastening member
50 Base member
50a First surface
50b Second surface
51 Planar portion
52 Wall portion
53 Fixing portion
53h Attachment hole
54 Pedestal portion
55 Accommodation portion
55B Accommodation portion
55C Accommodation portion
59 Insert nut
60 Insulation portion
61 Wall portion
61h Insertion hole
62 Peripheral wall portion
62h Insertion hole
62ha Insertion hole (first insertion hole)
62hb Insertion hole (second insertion hole)
62hc Insertion hole (third insertion hole)
62hd Insertion hole (fourth insertion hole)
63 Inner wall portion
63A Inner wall portion (first inner wall portion)
63B Inner wall portion (second inner wall portion)
63p Protrusion
63s Inclined surface
CM Cooling member
CS Cooling surface
MU Main body
R Region

What is claimed is:

1. An electrical connection unit comprising:
an electronic component that has a first terminal;
a first metal block that is adjacent to the first terminal in a first direction and electrically connected to the first terminal; and
an insulation portion,
wherein the first metal block has an end surface in the first direction and a peripheral surface extending from a peripheral edge of the end surface in the first direction, and
the insulation portion covers at least a part of the peripheral surface.

2. The electrical connection unit according to claim 1,
wherein the insulation portion has a wall portion that overlaps the end surface in the first direction and a peripheral wall portion that extends from a peripheral edge of the wall portion in the first direction, and
the peripheral wall portion covers the first metal block when viewed from a second direction intersecting the first direction.

3. The electrical connection unit according to claim 2,
wherein the peripheral wall portion has an insertion hole that is open in a third direction intersecting the first direction and the second direction.

4. The electrical connection unit according to claim 3,
wherein the insertion hole includes a first insertion hole and a second insertion hole,
the first insertion hole is located on a first side in the third direction, and
the second insertion hole is located on a second side in the third direction.

5. The electrical connection unit according to claim 1,
wherein the insulation portion integrally holds the first metal block.

6. The electrical connection unit according to claim 1, further comprising a second metal block,
wherein the electronic component further has a second terminal,
the insulation portion integrally holds the first metal block and the second metal block, and
the second metal block is adjacent to the second terminal in the first direction and connected to the second terminal.

7. The electrical connection unit according to claim 6,
wherein the electronic component further has an insulation rib that insulates the first terminal from the second terminal, and
the insulation portion has a first inner wall portion that insulates the first terminal from the second terminal together with the insulation rib.

8. The electrical connection unit according to claim 7,
wherein the insulation portion further has a second inner wall portion,
the first inner wall portion and the second inner wall portion are disposed between the first terminal and the second terminal, and
the first inner wall portion sandwiches the insulation rib with the second inner wall portion.
